(19) United States
(12) Patent Application Publication
(10) Pub. No.: US 2015/0040389 A1
(43) Pub. Date: Feb. 12, 2015

(54) METHOD FOR MANUFACTURING WIRING BOARD WITH BUILT-IN ELECTRONIC COMPONENT

(71) Applicant: IBIDEN CO., LTD., Ogaki-shi (JP)

(72) Inventors: Naohito ISHIGURO, Ogaki-shi (JP); Yasushi INAGAKI, Ogaki-shi (JP)

(73) Assignee: IBIDEN CO., LTD., Ogaki-shi (JP)

(21) Appl. No.: 14/454,879

(22) Filed: Aug. 8, 2014

(30) Foreign Application Priority Data
Aug. 9, 2013 (JP) 2013-165661

(51) Int. Cl. H05K 3/30

(52) U.S. Cl. CPC H05K 3/30
USPC 29/832

(57) ABSTRACT

A method for manufacturing a wiring board with a built-in electronic component includes positioning an electronic component in a cavity of a substrate, forming intermediate structures each including an intermediate insulation layer and an intermediate wiring-pattern layer on upper and lower surfaces of the substrate, respectively, such that a component-accommodating substrate is formed, attaching a support sheet to a first surface of the component-accommodating substrate, forming a connection layer including insulation layers and wiring-pattern layers on a second surface of the component-accommodating substrate on the opposite side with respect to the first surface of the component-accommodating substrate, removing the support sheet from the component-accommodating substrate such that an intermediate laminate structure having the connection layer laminated on the second surface of the component-accommodating substrate is formed, and forming upper-layer structures each including an insulation layer and a wiring-pattern layer on upper and lower surfaces of the intermediate laminate, respectively.

### CROSS-REFERENCE TO RELATED APPLICATIONS

The present application is based upon and claims the benefit of priority to Japanese Patent Application No. 2013-165661, filed Aug. 9, 2013, the entire contents of which are incorporated herein by reference.

### BACKGROUND OF THE INVENTION

1. Field of the Invention

The present invention relates to a method for manufacturing a wiring board with a built-in electronic component, more specifically, to a method for manufacturing a wiring board with a built-in electronic component, to include accommodating an electronic component in a cavity formed in an inner layer of a wiring board.

2. Description of Background Art

An electronic component in a wiring board may be mounted on a surface of the wiring board, or it may be mounted in a hole (cavity) formed in the wiring board. JP2010-171413A describes a method for mounting an electronic component in a cavity of a wiring board. JP2010-171413A describes a method that uses an adhesive tape for mounting an electronic component inside a wiring board. An adhesive tape is laminated on a surface of a substrate to cover a cavity opening on the surface. The adhesive surface of the adhesive tape is exposed inside the cavity. An electronic component is accommodated into the cavity through the opening on another surface on the opposite side.

The electronic component is preliminarily fixed by being adhered to the exposed adhesive surface. Then, a resin insulation layer is formed on the surface of the substrate with the accommodated electronic component, and the adhesive tape on the other surface is removed. Another resin insulation layer is formed on the other surface as well, and a wiring board with a built-in electronic component is completed. The entire contents of this publication are incorporated herein by reference.

### SUMMARY OF THE INVENTION

According to one aspect of the present invention, a method for manufacturing a wiring board with a built-in electronic component includes positioning an electronic component in a cavity of a substrate, forming intermediate structures each including an intermediate insulation layer and an intermediate wiring-pattern layer on upper and lower surfaces of the substrate, respectively, such that a component-accommodating substrate is formed, attaching a support sheet to a first surface of the component-accommodating substrate, forming a connection layer including insulation layers and wiring-pattern layers on a second surface of the component-accommodating substrate on the opposite side with respect to the first surface of the component-accommodating substrate, removing the support sheet from the component-accommodating substrate such that an intermediate laminate structure having the connection layer laminated on the second surface of the component-accommodating substrate is formed, and forming upper-layer structures each including an insulation layer and a wiring-pattern layer on upper and lower surfaces of the intermediate laminate, respectively.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to an embodiment;

FIG. 2 is a cross-sectional view of a laminated substrate used as a starting material in an embodiment;

FIG. 3 is a plan view of the laminated substrate;

FIG. 4 is a cross-sectional view showing a state where a cavity is formed in the laminated substrate;

FIG. 5 is a cross-sectional view showing a state where adhesive tape is laminated on the laminated substrate;

FIG. 6 is a cross-sectional view showing a state where an MLCC is accommodated in the cavity of the laminated substrate;

FIG. 7 is a cross-sectional view showing a state where an insulation layer is formed on a surface of the laminated substrate opposite the adhesive tape;

FIG. 8 is a cross-sectional view showing a state where the adhesive tape has been removed from the laminated substrate;

FIG. 9 is a cross-sectional view showing a state where an insulation layer is formed on the surface of the laminated substrate from which the adhesive tape has been removed;

FIG. 10 is a cross-sectional view of a component-accommodating substrate;

FIG. 11 is a cross-sectional view showing a state where a support sheet is attached to the component-accommodating substrate;

FIG. 12 is a cross-sectional view showing a state where a section to become a connection layer is formed on the component-accommodating substrate;

FIG. 13 is a cross-sectional view of an intermediate laminate taken out by edge processing; and

FIG. 14 is a cross-sectional view showing another example of a laminated substrate as a starting material.

### DETAILED DESCRIPTION OF THE EMBODIMENTS

The embodiments will now be described with reference to the accompanying drawings, wherein like reference numerals designate corresponding or identical elements throughout the various drawings.

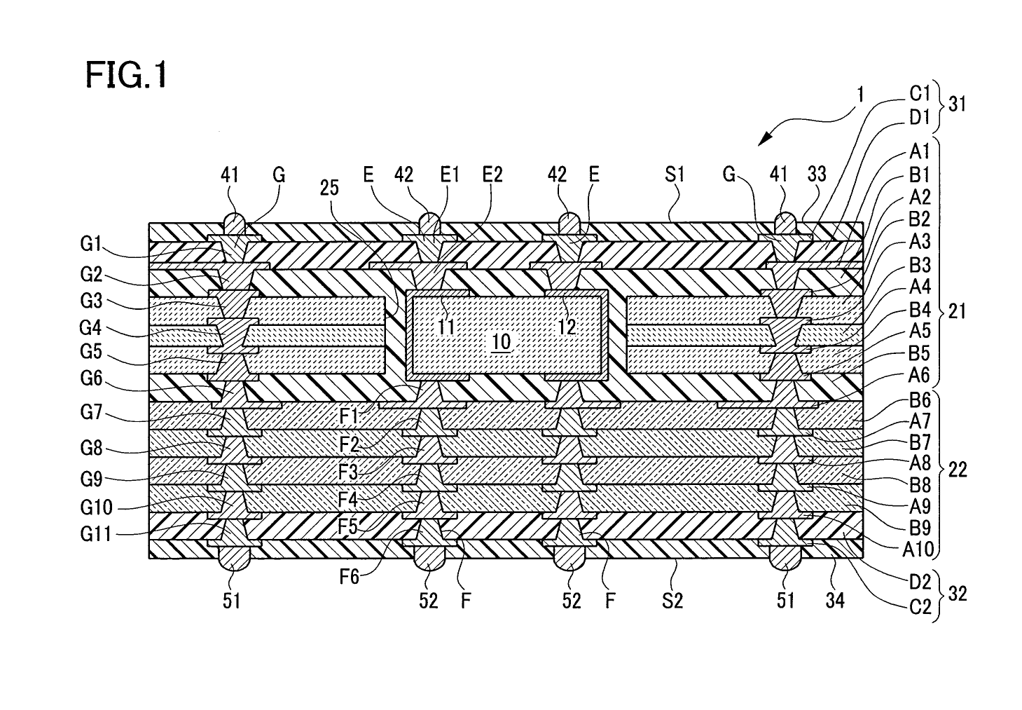

FIG. 1 shows wiring board 1 manufactured by a method according to the present embodiment. Wiring board 1 of the present embodiment is a multilayer wiring board formed by laminating multiple conductive wiring layers having wiring patterns and insulation layers for insulating the wiring layers from each other. Of both end surfaces in a lamination direction, the upper surface of wiring board 1 shown in FIG. 1 is referred to as first main surface (S1) and the lower surface opposite first main surface (S1) in FIG. 1 is referred to as second main surface (S2).

As shown in FIG. 1, wiring board 1 includes upper-layer section 31, component-accommodating layer 21, connection layer 22 and upper-layer section 32, which are formed in that order from the upper side. On the upper and lower surfaces of wiring board 1 in FIG. 1, solder-resist layers (33, 34) as protective layers are provided on upper-layer sections (31, 32). Upper-layer section 31 has upper wiring layer (C1) and upper insulation layer (D1). In upper wiring layer (C1), bumps (41, 42) are provided to penetrate through solder-resist layer 33 and to protrude upward from first main surface (S1). Upper-layer section 32 has upper wiring layer (C2) and upper insulation layer (D2). In upper wiring layer (C2), bumps (51, 52) are provided to penetrate through solder-resist layer 34 and to protrude downward from second main surface (S2).

In the final product, an IC chip will be mounted on first main surface (Si) of wiring board 1 of the present embodiment. Also, wiring board 1 is installed on another board such as a motherboard using second main surface (S2). Bumps (41, 42, 51, 52) are each made for external electrical access to wiring board 1.

As shown in FIG. 1, in component-accommodating layer 21 and connection layer 22 in wiring board 1 of the present embodiment, there are total 10 intermediate wiring layers (A1˜A10) and total nine intermediate insulation layers (B1˜B9) for insulating those intermediate wiring layers (A) from each other. In addition, electronic component 10 is built into component-accommodating layer 21. In particular, electronic component 10 is built into cavity 25, which penetrates through intermediate insulation layers (B2˜B4) of component-accommodating layer 21 in a lamination direction. In the present embodiment, electronic component 10 is a multilayer ceramic capacitor and is referred to as MLCC 10 in the following. As a whole, MLCC 10 is shaped as a rectangular plate, and both of its end surfaces in the left and right directions in FIG. 1 are covered with electrodes (11, 12). Electrodes (11, 12) are conductive portions connected to the inner conductors of MLCC 10. In addition, MLCC 10 of the present embodiment is for supplying power to an IC chip mounted on first main surface (S1) in the final product.

As shown in FIG. 1, stacked vias (E) are provided on the upper side of MLCC 10 in FIG. 1 for connecting electrodes (11, 12) to bumps 42. Stacked vias (E) are formed by stacking filled vias (E1, E2) formed respectively in insulation layers (D1, B1) of component-accommodating layer 21 and upper-layer section 31 positioned above MLCC 10 in FIG. 1. Also, below MLCC 10 in FIG. 1, stacked vias (F) are provided to connect electrodes (11, 12) to bumps 52. Stacked vias (F) are formed by stacking filled vias (F1˜F6) formed respectively in insulation layers (B5˜B6, D2) of component-accommodating layer 21, connection layer 22 and upper-layer section 32 positioned under MLCC 10 in FIG. 1.

Moreover, in wiring board 1 of the present embodiment, through-stacked vias (G) are provided for connecting bump 41 on the first-main-surface (S1) side and bump 51 on the second-main-surface (S2) side. The through-stacked vias (G) are structured by stacking filled vias (G1˜G11) formed respectively in all the insulation layers (D1, B1˜B9, D2) of component-accommodating layer 21, connection layer 22 and upper-layer sections (31, 32). In addition, as shown in wiring board 1 in FIG. 1, there are fewer wiring layers and insulation layers laminated on the upper side of MLCC 10 in FIG. 1 than on the lower side of MLCC 10 in FIG. 1. Therefore, MLCC 10 is built into wiring board 1 in a position closer to first main surface (S1) than to second main surface (S2) in a lamination direction.

Next, a process for manufacturing wiring board 1 of the present embodiment is described. The manufacturing process of wiring board 1 includes steps 1˜5 below. Descriptions will be provided in the order shown below.

1. Preparation of Component-Accommodating Substrate
1-1. Formation of Cavity
1-2. Accommodation of MLCC
1-3. Formation of Upper and Lower Layers

2. Attachment of Support Sheet

3. Formation of Connection Layer

4. Removal of Support Sheet

5. Formation of Upper-Layer Section and Others

Preparation of Component-Accommodating Substrate

First, a description is provided below of a method for manufacturing a component-accommodating substrate that corresponds to component-accommodating layer 21 of wiring board 1 shown in FIG. 1.

Formation of Cavity

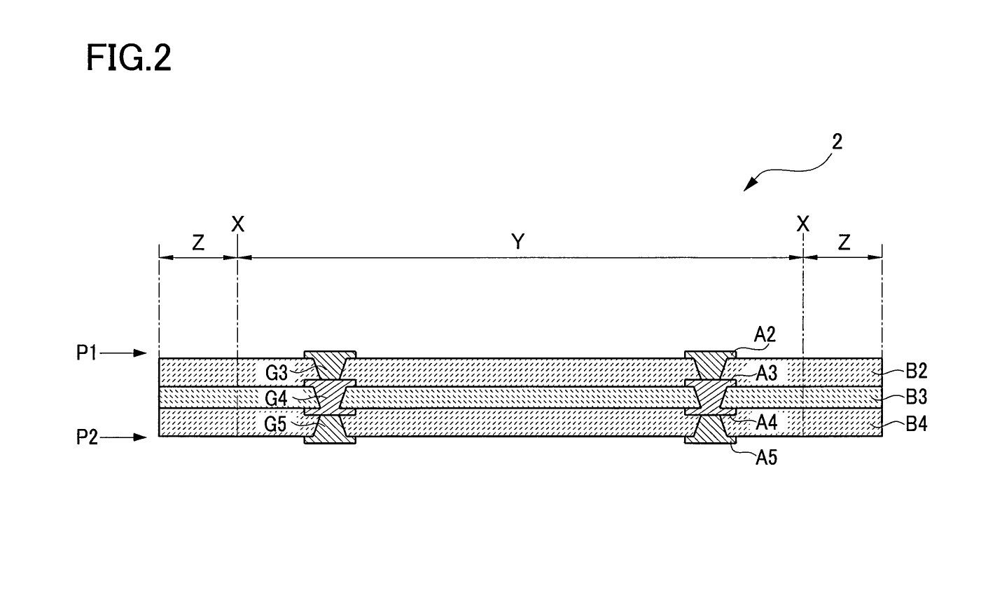

FIG. 2 shows laminated substrate 2 used as a starting material in the present embodiment. In FIG. 2, the upper part is the first-main-surface (S1) side and the lower part is the second-main-surface (S2) side of wiring board 1 shown in FIG. 1. Thus, the surface on the upper side of laminated substrate 2 in FIG. 2 is referred to as first surface (P1) and the surface on the lower side as second surface (P2). Laminated substrate 2 is formed with intermediate wiring layers (A2˜A5) and intermediate insulation layers (B2˜B4). Laminated substrate 2 is formed by laminating intermediate wiring layers (A2˜A5) with intermediate insulation layers (B2˜B4) each containing glass cloth (core material) that are disposed between the wiring layers. In addition, stacked filled vias (G3˜G5) are formed respectively in intermediate insulation layers (B2˜B4).

More specifically, first, intermediate insulation layer (B3) (containing core material) with copper foil attached to both surfaces is prepared, and penetrating holes are formed using a laser or the like in portions that subsequently become filled vias (G4). Next, copper plating is performed on the entire surface. The penetrating holes are filled with plating, and filled vias (G4) are formed. Also, copper-plated layers are formed on the copper foil on both surfaces of intermediate insulation layer (B3). Then, copper-plated layers on surfaces of intermediate insulation layer (B3) are patterned to form intermediate wiring layers (A3, A4). Next, on upper and lower surfaces of intermediate insulation layer (B3) where intermediate wiring layers (A3, A4) are formed, prepreg is laminated to form intermediate insulation layers (B2, B4). The prepreg laminated here is made by impregnating core material with thermosetting insulative resin such as epoxy resin. Next, heat is applied to cure the laminated prepreg, and intermediate insulation layers (B2, B4) are formed. Then, holes are formed using a laser or the like in portions that subsequently become filled vias (G3, G5). Then, plating is performed on the entire surface to fill holes with plating, while plated layers are formed on surfaces of intermediate insulation layers (B2, B4). After that, the plated layers on surfaces of intermediate insulation layers (B2, B4) are patterned to form intermediate wiring layers (A2, A5). Accordingly, laminated substrate 2 is manufactured.

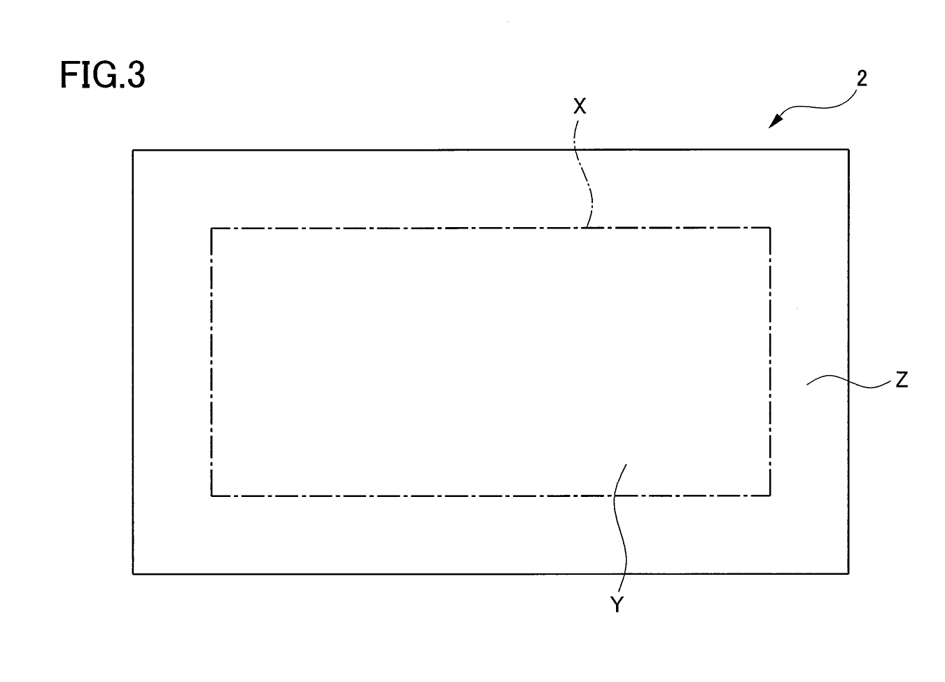

In addition, laminated substrate 2 has marginal region (Z) shown on the right or left side of dotted lines (X) as well as effective region (Y) positioned on the central side of marginal region (Z) as shown in FIG. 2. Upper layers will be laminated on effective region (Y), which subsequently becomes an inner layer of wiring board 1. On the other hand, marginal region (Z) is cut off in a later step of the manufacturing process and will be discarded. FIG. 3 is a plan view of laminated substrate 2, whose cross section is shown in FIG. 2. As shown in FIG. 3, marginal region (Z) in the present embodiment is formed along the periphery of laminated substrate 2 to surround effective region (Y).

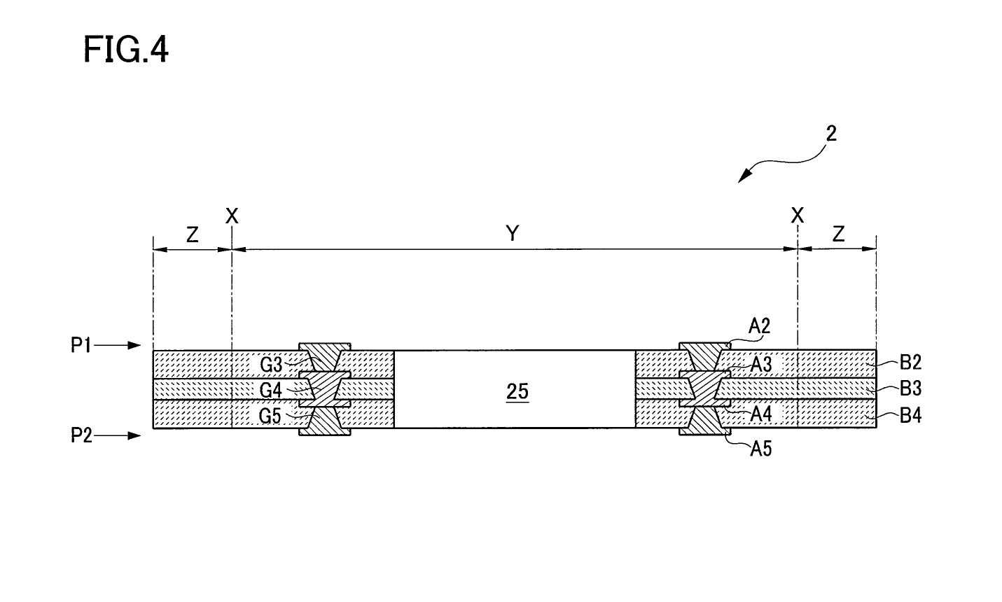

A laser or the like is used to form a penetrating hole in laminated substrate 2 in a state as shown in FIG. 2, and cavity 25 is formed as shown in FIG. 4. Cavity 25 is formed inside effective region (Y) of laminated substrate 2 as shown in FIG. 4. After cavity 25 is formed, desmearing treatment is performed to remove contaminants produced during the process for forming the cavity.

Accommodation of MLCC

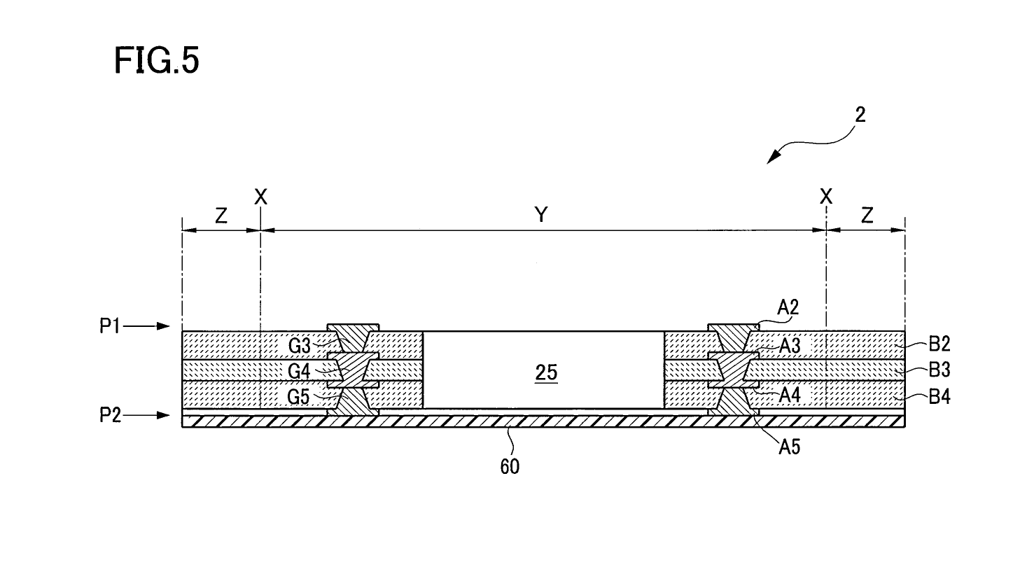

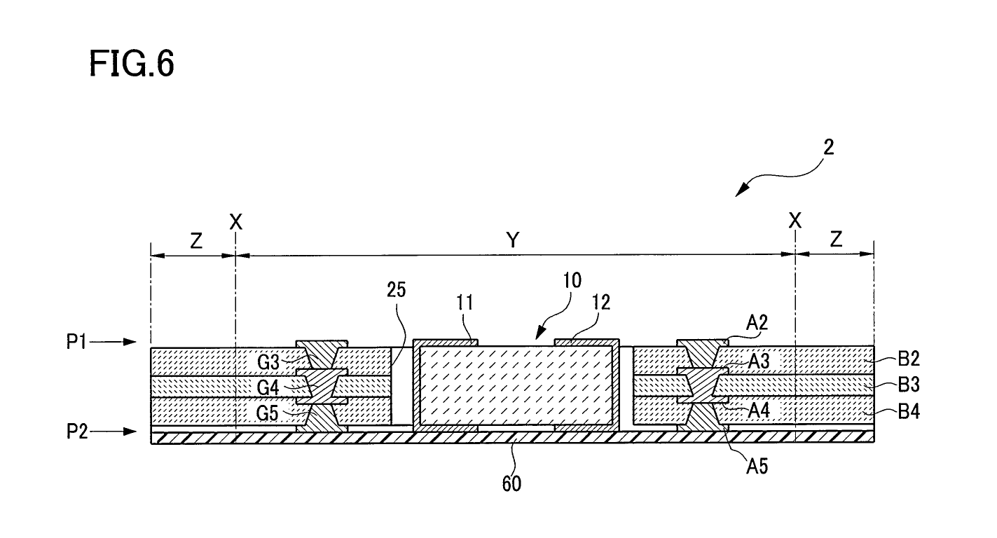

Next, MLCC 10 is accommodated in cavity 25 of laminated substrate 2. First, adhesive tape 60 is laminated on second surface (P2) of laminated substrate 2 to prepare a state shown in FIG. 5. The entire surface of one side of adhesive tape 60 is adhesive. The adhesive side is positioned to face second surface (P2) of laminated substrate 2. Examples of adhesive tape 60 are PET film and the like. Then, MLCC 10 is accommodated in cavity 25 prepared as shown in FIG. 5 to obtain a state shown in FIG. 6. The lower surface of MLCC 10 in FIG. 6 is laminated on the adhesive surface of adhesive tape 60 so as to be preliminarily fixed.

Formation of Upper and Lower Layers

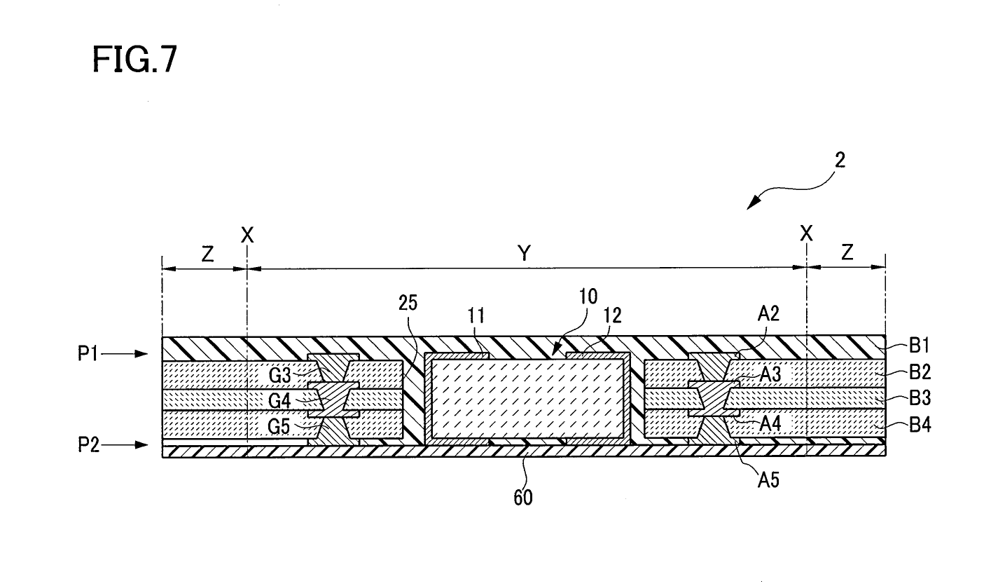

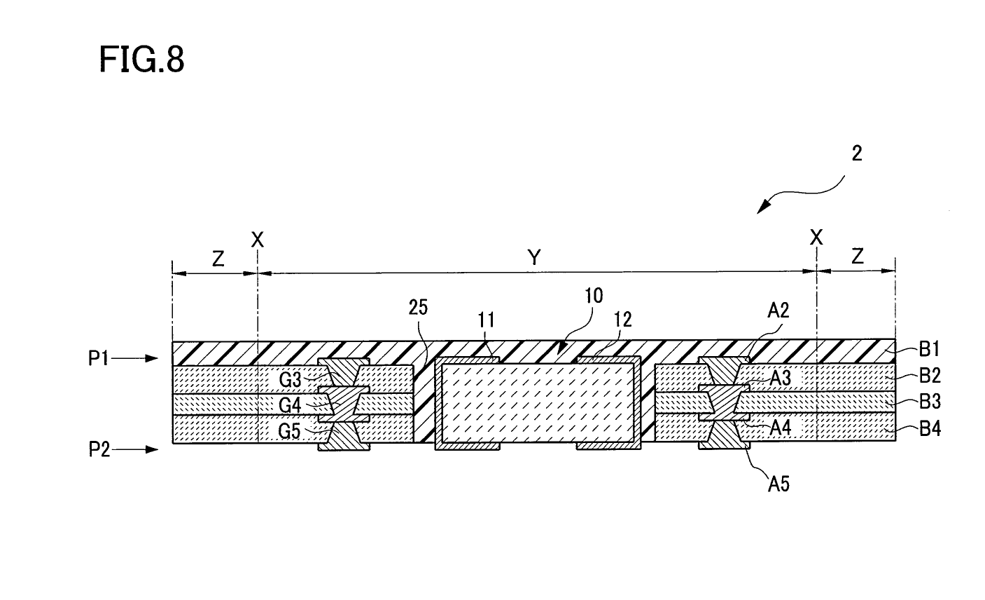

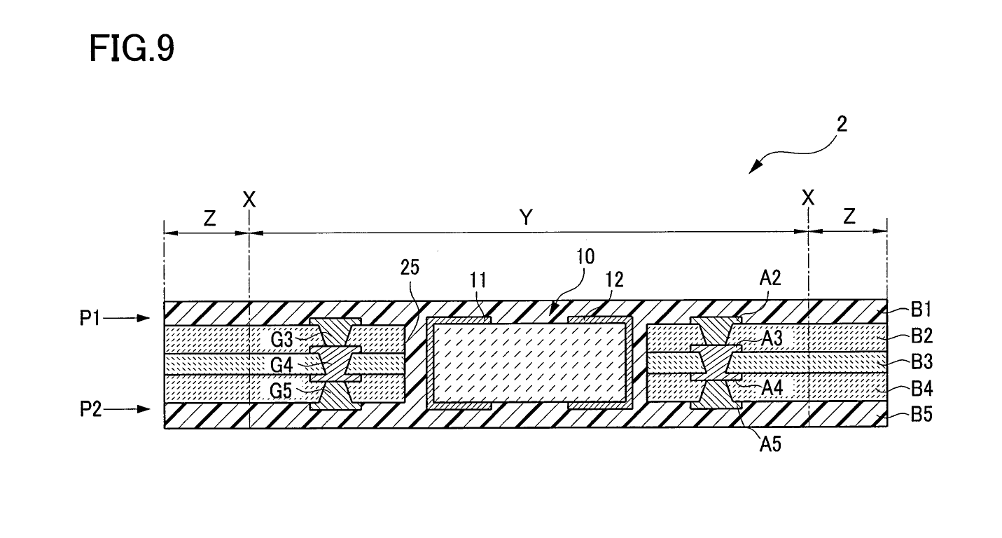

Next, insulation layers and the like are formed respectively on first surface (P1) and second surface (P2) of laminated substrate 2. For that purpose, prepreg made by impregnating core material with thermosetting insulative resin such as epoxy resin is laminated on first surface (P1) and second surface (P2) of laminated substrate 2 in the present embodiment. More specifically, first, prepreg is laminated on first surface (P1) of laminated substrate 2 prepared as shown in FIG. 6 to obtain a state shown in FIG. 7. In FIG. 7, intermediate insulation layer (B1) is formed on first surface (P1) of laminated substrate 2. In addition, portions except for MLCC 10 in cavity 25 are filled with part of the resin of the prepreg laminated on first surface (P1). Next, after adhesive tape 60 is removed (FIG. 8), prepreg is laminated on second surface (P2) of laminated substrate 2 to obtain a state shown in FIG. 9. Laminated substrate 2 shown in FIG. 9 has intermediate insulation layer (B5) formed on second surface (P2) in addition to intermediate insulation layer (B1) formed on first surface (P1).

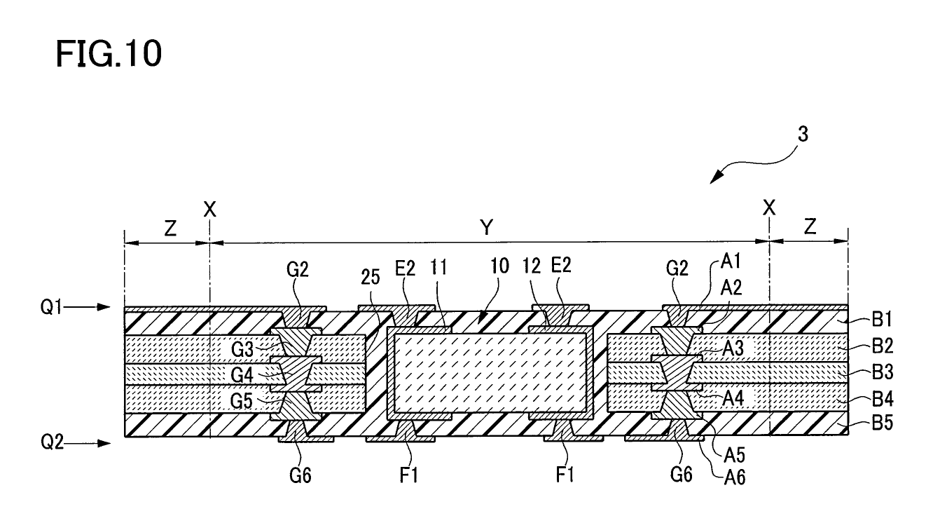

Next, curing treatment is performed on intermediate insulation layers (B1, B5). Namely, heat is applied to laminated substrate 2 after the above lamination so that the thermosetting resin is cured. Accordingly, MLCC 10 is fixed as shown in FIG. 9. After that, wiring layers and filled vias are respectively formed for intermediate insulation layers (B1, B5) to obtain a state shown in FIG. 10. In intermediate insulation layers (B1, B5) shown in FIG. 10, filled vias (E2, F1, G2, G6) are provided respectively, and those filled vias (E2, F1, G2, G6) are connected to intermediate wiring layers (A1, A6) formed on surfaces of intermediate insulation layers (B1, B5) respectively.

Furthermore, filled vias (E2) of intermediate insulation layer (B1) are connected to electrodes (11, 12) of MLCC 10 on the upper-surface side in FIG. 10. Filled vias (F1) of intermediate insulation layer (B5) are connected to electrodes (11, 12) of MLCC 10 on the lower-surface side in FIG. 10. In addition, filled vias (G2, G6) of intermediate insulation layers (B1, B5) are stacked directly on filled vias (G3, G5) in intermediate insulation layers (B2, B4) positioned on their respective lower sides. Intermediate wiring layers (A1, A6) and filled vias (E2, F1, G2, G6) are each formed by plating. Namely, in portions of intermediate insulation layers (B1, B5), holes are formed using a laser or the like in portions that subsequently become filled vias (E2, F1, G2, G6), and plating is performed on the entire surface. Then, plated layers on the surfaces of intermediate insulation layers (B1, B5) are patterned. According to the process described above, component-accommodating substrate 3 shown in FIG. 10 is obtained. Here, as shown in FIG. 10, a surface of the obtained component-accommodating substrate 3 positioned on the upper side of FIG. 10 is referred to as first surface (Q1), and a surface on the lower side is referred to as second surface (Q2). First surface (Q1) of component-accommodating substrate 3 is on the first-main-surface (S1) side of wiring board 1 in FIG. 1, and second surface (Q2) is on the second-main-surface (S2) side of wiring board 1.

Attachment of Support Sheet

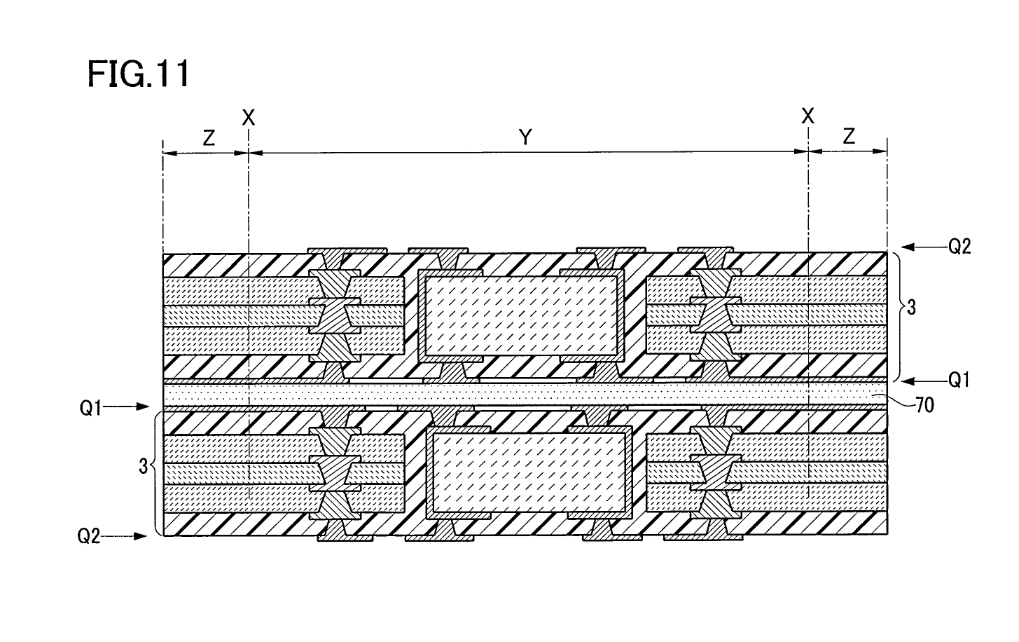

Next, component-accommodating substrate 3 is attached to support sheet 70 to obtain a state shown in FIG. 11. In FIG. 11, component-accommodating substrate 3 is attached to each of the upper and lower sides of support sheet 70. Both the upper and lower sides of support sheet 70 face first surface (Q1) of each component-accommodating substrate 3. Therefore, both upper- and lower-side surfaces of support sheet 70 shown in FIG. 11 are adhesive. However, the upper and lower surfaces of support sheet 70 are not entirely adhesive. Namely, the portion of support sheet 70 facing effective region (Y) of component-accommodating substrate 3 is not adhesive, and only the portion facing marginal region (Z) is adhesive. In addition, unlike adhesive tape 60 described above (FIG. 5 and the like), support sheet 70 is made of highly rigid material such as a double-sided copper-clad laminate or a metal sheet.

Formation of Connection Layer

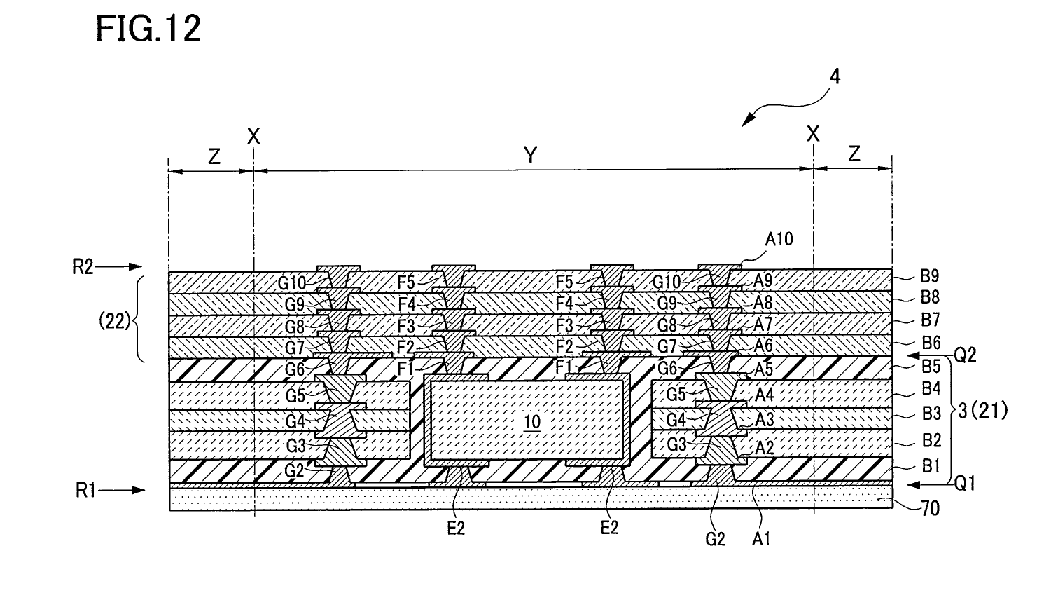

Next, insulation layers and wiring layers are laminated on second surface (Q2) of component-accommodating substrate 3 attached to support sheet 70 to obtain a state shown in FIG. 12. Here, component-accommodating substrate 3 laminated on the lower side of support sheet 70 is omitted in and subsequent to FIG. 12, and only component-accommodating substrate 3 on the upper side of support sheet 70 is described. The state in FIG. 12 is obtained by laminating consecutively upward from second surface (Q2) of component-accommodating substrate 3.

Namely, first, prepreg is laminated on second surface (Q2) of component-accommodating substrate 3 to form intermediate insulation layer (B6). The prepreg used in the present process is also made by impregnating core material with thermosetting insulative resin such as epoxy resin. Next, the laminated prepreg is cured by heat so as to form intermediate insulation layer (B6). Then, holes are made by a laser or the like in portions of intermediate insulation layer (B6) that subsequently become filled vias (F2, G7). Then, plating is performed to fill the holes with plating while a plated layer is formed on the surface of intermediate insulation layer (B6). After that, the plated layer on the surface of intermediate insulation layer (B6) is patterned to form intermediate wiring layer (A7). Accordingly, on second surface (Q2) of component-accommodating substrate 3, intermediate insulation layer (B6) is formed to have intermediate wiring layer (A7) and filled vias (F2, G7).

Moreover, by employing the same process as taken for intermediate wiring layer (A7) and intermediate insulation layer (B6), intermediate wiring layers (A8˜A10) and intermediate insulation layers (B7˜B9) are formed consecutively. In addition, filled vias (F3˜F5, G8˜G10) in intermediate insulation layers (B7˜B9) are also formed in the same manner as in filled vias (F2, G7) in intermediate insulation layer (B6). As shown in FIG. 12, filled vias (F2˜F5) in intermediate insulation layers (B6˜B9) formed in the present step are stacked consecutively directly on filled via (F1) in intermediate insulation layer (B5).

Moreover, filled vias (G7˜G10) in intermediate insulation layers (B6˜B9) are also stacked in that order directly on filled via (G6) in intermediate insulation layer (B5).

According to the process employed in the present step, laminate 4 is obtained as shown in FIG. 12, where a section to become connection layer 22 in wiring board 1 is provided on second surface (Q2) of component-accommodating substrate 3, which subsequently becomes component-accommodating layer 21 in wiring board 1. In addition, a surface of laminate 4 positioned on the lower side of FIG. 12 is referred to as first surface (R1), and a surface on the upper side is referred to as second surface (R2). First surface (R1) of laminate 4 is positioned on the first-main-surface (S1) side of wiring board 1 shown in FIG. 1, and second surface (R2) is on the second-main-surface (S2) side of wiring board 1. Here, regarding component-accommodating substrate 3 positioned on the lower side of support sheet 70 omitted in FIG. 12, by using the same process as on second surface (Q2) of component-accommodating substrate 3 on the upper side, a section to become connection layer 22 is formed on second surface (Q2) to obtain laminate 4. Regarding laminate 4 on the lower side of support sheet 70, the upper surface is referred to as first surface (R1) and the lower surface as second surface (R2).

Removal of Support Sheet

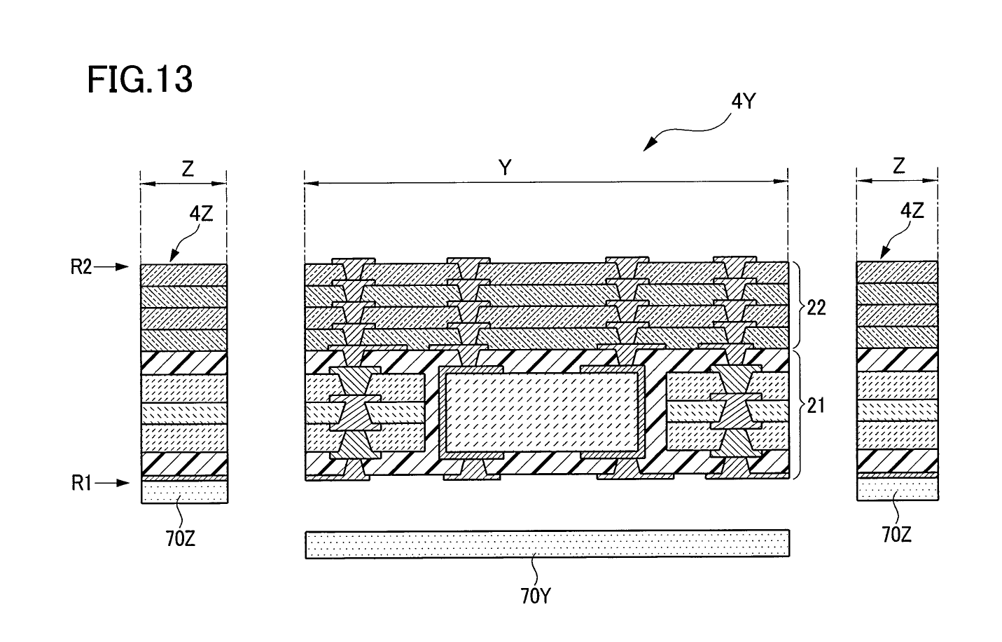

After the above procedures, support sheet 70 is removed from laminate 4 shown in FIG. 12. Support sheet 70 is removed together with laminate 4 by cutting edges along effective region (Y) of laminate 4. Namely, for example, a cutting tool longer than the length obtained by totaling the thickness of support sheet 70 and the thicknesses of laminates 4 on both sides of support sheet 70 is moved in marginal region (Z) along (X), which is the outline of effective region (Y) of laminate 4. Accordingly, as shown in FIG. 13, portions of laminates 4 and support sheet 70 except for effective region (Y) are cut off as laminate (4Z) and support sheet (70Z).

As described above, the surface of support sheet 70 is adhesive only in the portion facing marginal region (Z) of laminate 4. Thus, as shown in FIG. 13, intermediate laminate (4Y) corresponding to effective region (Y) of laminate 4 is separated from support sheet (70Y) which is the portion of support sheet 70 corresponding to effective region (Y), because the portion of support sheet (70Y) facing first surface (R1) of laminate (4Y) is not adhesive. Therefore, intermediate laminate (4Y) can be taken out. Also, regarding laminate 4 on the lower side of support sheet 70 omitted in FIG. 13, intermediate laminate (4Y) corresponding to effective region (Y) of laminate 4 is also taken out. Laminate (4Z), support sheet (70Z) and support sheet (70Y) are discarded after edge cutting.

Formation of Upper-Layer Section

Next, the rest of wiring board 1 is formed on intermediate laminate (4Y) taken out as shown in FIG. 13. Accordingly, wiring board 1 is completed. Namely, upper-layer sections (31, 32), solder-resist layers (33, 34) and bumps (41, 42, 51, 52) are formed on intermediate laminate (4Y).

To form upper-layer sections (31, 32), first, resin films for forming upper insulation layers (D1, D2) are respectively laminated on first surface (R1) and second surface (R2) of intermediate laminate (4Y). Resin films used here are made of thermosetting insulative resin that does not contain core material. Next, heat is applied to cure the laminated resin films, and upper insulation layers (D1, D2) are formed. Then, holes are formed by using a laser or the like in portions that subsequently become filled vias (E1, F6, G1, G11). Then, plating is performed to fill the holes with plating while plated layers are formed on surfaces of upper insulation layers (D1, D2). After that, upper wiring layers (C1, C2) are formed by patterning the plated layers on surfaces of upper insulation layers (D1, D2).

Filled vias (E1) formed in upper insulation layer (D1) are stacked directly on filled vias (E2) in intermediate insulation layer (B1) positioned on the lower side. Accordingly, stacked vias (E) are formed to electrically connect bumps 42 and electrodes (11, 12) of electronic component 10. In addition, filled vias (F6) in upper insulation layer (D2) are stacked directly on filled vias (F5) in intermediate insulation layer (B9) positioned on the lower side. Accordingly, stacked vias (F) are formed to electrically connect bumps 52 and electrodes (11, 12) of electronic component 10. Moreover, filled vias (G1, G11) in upper insulation layers (D1, D2) are respectively stacked directly on filled vias (G2, G10) in intermediate insulation layers (B1, B9) positioned under upper insulation layers (D1, D2). Accordingly, through-stacked vias (G) are formed to electrically connect bumps 41 and bumps 51.

Next, solder-resist layers (33, 34) are formed on surfaces of upper-layer sections (31, 32) while portions for forming bumps (41, 42, 51, 52) of upper wiring layers (C1, C2) are exposed. Then, bumps (41, 42, 51, 52) are formed on the exposed portions of upper wiring layers (C1, C2). Accordingly, wiring board 1 shown in FIG. 1 is obtained.

In wiring board 1 as manufactured above, MLCC 10 is built into wiring board 1 in a position closer to first main surface (S1) than to second main surface (S2) in a lamination direction as described above. Namely, the length of wiring formed by stacked vias (E) is short between an IC chip mounted on first main surface (S1) of wiring board 1 and built-in MLCC 10. Accordingly, change in load or occurrence of noise during operations of a final product are reduced by using wiring board 1 of the present embodiment.

In addition, warping is suppressed in wiring board 1 despite the built-in position of MLCC 10, which is significantly shifted toward the first-main-surface (S1) side. That is because connection layer 22 is formed on second surface (Q2) of component-accommodating substrate 3 while first surface (Q1) of substrate 3 is still attached to support sheet 70. Namely, in component-accommodating substrate 3, when connection layer 22 is formed only on the second-surface (Q2) side (FIG. 12), the amount of stress is different on the first-surface (Q1) side from that on the second-surface (Q2) side. However, in the method for manufacturing wiring board 1 according to the present embodiment, since first main surface (Q1) of component-accommodating substrate 3 is attached to highly rigid support sheet 70 when connection layer 22 is formed, differences in stress on the first-surface (Q1) side and the second-surface (Q2) side will not cause warping in component-accommodating substrate 3. In addition, to ensure the effect of suppressing warping of component-accommodating substrate 3, the rigidity of support sheet 70 is preferred to be higher than that of the section to become connection layer 22 laminated on second surface (Q2) of component-accommodating substrate 3.

Moreover, regarding intermediate laminate (4Y) after being separated from support sheet 70, upper-layer sections (31, 32) having the same number of layers are laminated on first surface (R1) and second surface (R2). Namely, there is no difference generated in the stress on the first-surface (R1) side and the stress on the second-surface (R2) side of intermediate laminate (4Y). Accordingly, no warping occurs.

In the present embodiment, while component-accommodating substrates 3 are still attached to the upper and lower sides of support sheet 70 (FIG. 11), a section to become connection layer 22 is formed (FIG. 12). By so doing, two intermediate laminates (4Y) are obtained using one support sheet 70. Namely, productivity of wiring board 1 is enhanced. It is an option to manufacture intermediate laminate (4Y) with component-accommodating substrate 3 attached only to one side of support sheet 70.

As described in detail above, the method for manufacturing wiring board 1 according to the present embodiment is characterized by the following. First, component-accommodating substrate 3 that becomes component-accommodating layer 21 in wiring board 1 is manufactured. To obtain component-accommodating substrate 3, MLCC 10 is accommodated in cavity 25 of laminated substrate 2 as a starting material and then intermediate insulation layers (B1, B5) and intermediate wiring layers (A1, A6) are respectively formed on first surface (P1) and second surface (P2). Next, support sheet 70 is attached to first surface (Q1) of component-accommodating substrate 3, and intermediate insulation layers (B6˜B9) and intermediate wiring layers (A7˜A10), which subsequently make connection layer 22, are formed on second surface (Q2). Then, support sheet 70 is removed by edge cutting and intermediate laminate (4Y) is taken out. After that, upper-layer sections (31, 32) and so on are formed to obtain wiring board 1. Because highly rigid support sheet 70 is attached to first surface (Q1) of component-accommodating substrate 3, warping is suppressed when the section to become connection layer 22 is formed on second surface (Q2). The method for manufacturing a wiring board with a built-in electronic component is capable of suppressing warping of a wiring board, even though a number of layers is different on the upper and lower surfaces of the layer where an electronic component is accommodated.

The present embodiment is described simply to show an example, and does not limit the present invention. Thus, various improvements and modifications are possible within a scope that does not deviate from the gist of the present invention. For example, the electronic component to be accommodated in cavity 25 is not limited to MLCC 10, and may be an inductor, resistor or filter. Moreover, in the above embodiment, stacked vias (E, F) are provided respectively on both surfaces of electrodes (11, 12) of MLCC 10. However, that is not the only option, and only stacked vias (E) may be formed without forming stacked vias (F). Also, if wiring board 1 is manufactured, for example, by setting second surface (Q2) of component-accommodating substrate 3 on the first-main-surface (S1) side of wiring board 1 and first surface (Q1) on the first-main-surface (S2) side, second surface (Q2) of component-accommodating substrate 3 is attached to support sheet 70.

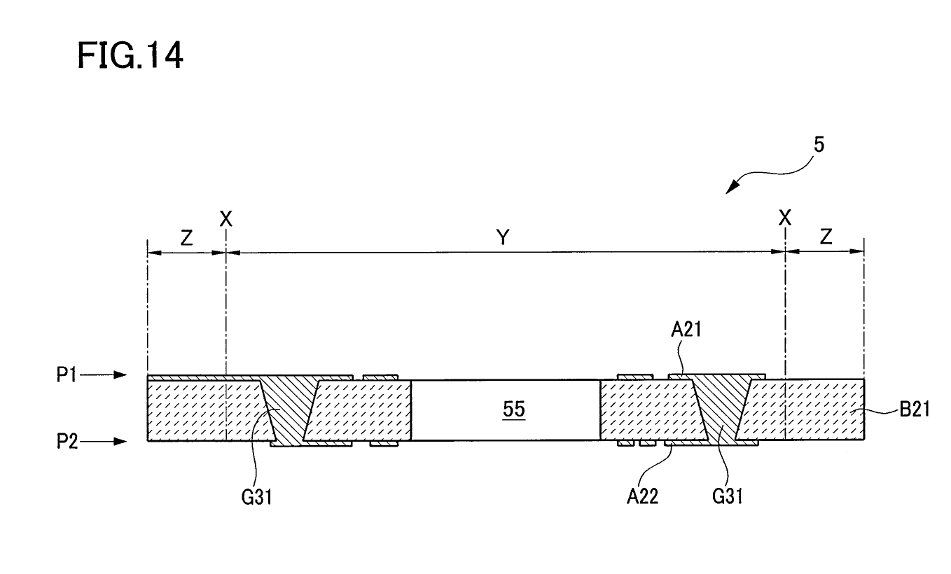

In addition, in the embodiment above, laminated substrate 2 with three intermediate insulation layers (B2˜B4) (see FIG. 4 and others) is used as a starting material; however, that is not the only option. For example, laminated substrate 5 having only a single intermediate insulation layer (B21) as shown in FIG. 14 may also be used as a starting material. Laminated substrate 5 has intermediate wiring layers (A21, A22) on both surfaces of intermediate insulation layer (B21) and filled vias (G31) formed in intermediate insulation layer (B21) as shown in FIG. 14. Further, in effective region (Y) of laminated substrate 5, cavity 55 is formed to accommodate MLCC 10. The method employed for forming laminated substrate 2 above may also be used for forming laminated substrate 5. Alternatively, a substrate having two intermediate insulation layers or four or more intermediate insulation layers may be used instead of laminated substrate 2. Yet alternatively, laminated substrate 2 may have a through-hole filled via conductor instead of a filled via (G4) to electrically connect intermediate wiring layers (A3, A4).

Moreover, the embodiment above has described an example in which prepreg made by impregnating core material with thermosetting insulative resin is used for forming intermediate insulation layers (B1, B5) (FIG. 10) and intermediate insulation layers (B6˜B9) (FIG. 12). However, the present invention is not limited to such an example. Namely, to form those intermediate insulation layers (B), resin film that does not contain core material may also be used. Also, connection layer 22 is made of four layers in the above embodiment, but it may be made of three or fewer layers or five or more layers. In addition, upper-layer sections (31, 32) are not limited to being single-layered, but there may be two or more layers. Furthermore, upper insulation layers (D) of upper-layer sections (31, 32) may be formed using prepreg that contains core material.

A wiring board is becoming more multilayered in response to the development of highly functional diverse electronic devices. For example, when a built-in electronic component is a capacitor as a power source for an IC chip to be mounted on the wiring board, the position of the capacitor is preferred to be closer to the board surface where an IC chip is to be mounted. That is because change in load and occurrence of noise during the operation are reduced by shortening the length of wiring between the IC chip and the capacitor and by reducing inductance components. A number of upper layers on a laminated substrate with an accommodated capacitor may be the same on its first-main surface side and second-main surface side. When the number of laminated layers on one main-surface side is greater than the number of laminated layers on the other main-surface side, warping occurs in the subsequently obtained wiring board due to the difference in the number of laminated layers. Accordingly, in a wiring board manufactured with the same number of upper layers on its first-main surface side and second-main surface side , the capacitor is accommodated in the center of a lamination direction. Namely, wiring length is unable to be shortened from a capacitor accommodated in the center of a wiring board in a lamination direction to the IC chip mounted on a surface of the wiring board.

A method for manufacturing a wiring board with a built-in electronic component according to an embodiment of the present invention is capable of suppressing warping of a wiring board where a number of laminated layers is set different on the upper and lower sides of the layer where an electronic component is accommodated.

In a method for manufacturing a wiring board with a built-in electronic component according to an embodiment of the present invention, the wiring board is structured to have multiple laminated insulation layers and wiring-pattern layers and to accommodate an electronic component in a cavity formed in an inner layer of its laminated structure. Such a manufacturing method is characterized by the following: positioning an electronic component in a cavity of a laminated substrate having insulation layers and wiring-pattern layers, and then forming a component-accommodating substrate by providing insulation layers and wiring-pattern layers on both upper and lower surfaces of the laminated substrate; attaching a support sheet to a first surface of the component-accommodating substrate; laminating insulation layers and wiring-pattern layers on a second surface opposite the first surface of the component-accommodating substrate; forming an intermediate laminate by removing the support sheet from the component-accommodating substrate where insulation layers and wiring-pattern layers are laminated on the second surface; and forming upper-layer sections by laminating insulation layers and wiring-pattern layers on both upper and lower surfaces of the intermediate laminate.

In a method for manufacturing a wiring board with a built-in electronic component according to an embodiment of the present invention, insulation layers and wiring-pattern layers are laminated on the second surface after a support sheet has been attached to the first surface of a component-accommodating substrate. Thus, warping of the component-accommodating substrate is suppressed even when insulation layers and wiring-pattern layers are laminated only on the second surface. In addition, since insulation layers and wiring-pattern layers are laminated only on the second-surface side of the component-accommodating substrate, the number of laminated layers is set to be greater on the second-surface side than on the first-surface side. Namely, warping of the wiring board is suppressed while a different number of laminated layers is formed on the upper and lower sides of the component-accommodating substrate.

In addition, in the method for manufacturing a wiring board with a built-in electronic component above, it is preferred to set the number of layers in each upper section to be the same on the upper- and lower-surface sides of the intermediate laminate, because such a setting allows upper-layer sections to be laminated on the upper and lower surfaces of the intermediate laminate while warping is suppressed.

Furthermore, in the method for manufacturing a wiring board with a built-in electronic component above, the laminated substrate may be a multilayer substrate formed by laminating multiple insulation layers and wiring-pattern layers.

In the method for manufacturing a wiring board with a built-in electronic component above, it is an option to use a laminated substrate having wiring-pattern layers provided on the upper and lower surfaces and having a via conductor that connects the wiring-pattern layers to each other, and to form a filled via stacked on the via conductor or on a filled via stacked on the via conductor when insulation layers are laminated on the upper and lower surfaces of the laminated substrate.

In the method for manufacturing a wiring board with a built-in electronic component above, it is preferred to set a surface of the component-accommodating substrate, which is the surface for mounting an IC chip on a final product, to be a first surface, while setting another surface, which is the surface for connection with another substrate on the final product, to be a second surface. On the first-surface side of the component-accommodating substrate, there are fewer laminated layers than on the second-surface side. Namely, by setting as above, the distance between the electronic component and the surface for mounting an IC chip is made closer in the wiring board as a final product, and the length of wiring is shortened between the electronic component and the IC chip.

In the method for manufacturing a wiring board with a built-in electronic component above, two substrates each having an accommodated component are preferred to be attached to the upper and lower sides of a support sheet in such a way that their respective first surfaces face the support sheet. That is because two wiring boards each having a built-in electronic component are manufactured using one support sheet, thereby enhancing the productivity of manufacturing a wiring board with a built-in electronic component.

A method for manufacturing a wiring board with a built-in electronic component according to an embodiment of the present invention suppresses warping of the wiring board where a different number of laminated layers is formed on the upper and lower sides of a layer where an electronic component is accommodated.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a wiring board with a built-in electronic component, comprising:
positioning an electronic component in a cavity of a substrate;
forming a plurality of intermediate structures each comprising an intermediate insulation layer and an intermediate wiring-pattern layer on upper and lower surfaces of the substrate, respectively, such that a component-accommodating substrate is formed;
attaching a support sheet to a first surface of the component-accommodating substrate;
forming a connection layer comprising a plurality of insulation layers and a plurality of wiring-pattern layers on a second surface of the component-accommodating substrate on an opposite side with respect to the first surface of the component-accommodating substrate;
removing the support sheet from the component-accommodating substrate such that an intermediate laminate structure comprising the connection layer laminated on the second surface of the component-accommodating substrate is formed; and
forming a plurality of upper-layer structures each comprising an insulation layer and a wiring-pattern layer on upper and lower surfaces of the intermediate laminate, respectively.

2. A method for manufacturing a wiring board according to claim 1, wherein the plurality of upper-layer structures is formed such that the upper-layer structures have a same number of insulation layers on the upper and lower surfaces of the intermediate laminate.

3. A method for manufacturing a wiring board according to claim 1, wherein the substrate is a laminated substrate comprising a plurality of insulation layers and a plurality of wiring-pattern layers.

4. A method for manufacturing a wiring board according to claim 2, wherein the substrate is a laminated substrate comprising a plurality of insulation layers and a plurality of wiring-pattern layers.

5. A method for manufacturing a wiring board according to claim 1, wherein the substrate has a plurality of wiring-pattern layers formed on opposite surfaces of the substrate respectively and at least one via conductor connecting the wiring-pattern layers of the substrate, and the forming of the connection layer includes forming a plurality of filled via conductors through the insulation layers in the connection layers such that the plurality of via conductors is stacked on the via conductor in the substrate and is stacked one another to form a stacked via structure.

6. A method for manufacturing a wiring board according to claim 2, wherein the substrate has a plurality of wiring-pattern layers formed on opposite surfaces of the substrate respectively and at least one via conductor connecting the wiring-pattern layers of the substrate, and the forming of the connection layer includes forming a plurality of filled via conductors through the insulation layers in the connection layers such that the plurality of via conductors is stacked on the via conductor in the substrate and is stacked one another to form a stacked via structure.

7. A method for manufacturing a wiring board according to claim 3, wherein the plurality of wiring-pattern layers in the substrate includes outer wiring-pattern layers formed on opposite surfaces of the substrate respectively and a plurality of stacked via conductors connecting the outer wiring-pattern layers, and the forming of the connection layer includes forming a plurality of filled via conductors through the insulation layers in the connection layers such that the plurality of via conductors is stacked on the stacked via conductors in the substrate and is stacked one another to form a stacked via structure.

8. A method for manufacturing a wiring board according to claim 4, wherein the plurality of wiring-pattern layers in the substrate includes outer wiring-pattern layers formed on opposite surfaces of the substrate respectively and a plurality of stacked via conductors connecting the outer wiring-pattern layers, and the forming of the connection layer includes forming a plurality of filled via conductors through the insulation layers in the connection layers such that the plurality of via conductors is stacked on the stacked via conductors in the substrate and is stacked one another to form a stacked via structure.

9. A method for manufacturing a wiring board according to claim 1, wherein the component-accommodating substrate is formed such that the first surface of the component-accommodating substrate forms an IC mounting side and the second surface of the component-accommodating substrate forms a second wiring board connection side.

10. A method for manufacturing a wiring board according to claim 2, wherein the component-accommodating substrate is formed such that the first surface of the component-accommodating substrate forms an IC mounting side and the second surface of the component-accommodating substrate forms a second wiring board connection side.

11. A method for manufacturing a wiring board according to claim 3, wherein the component-accommodating substrate is formed such that the first surface of the component-accommodating substrate forms an IC mounting side and the second surface of the component-accommodating substrate forms a second wiring board connection side.

12. A method for manufacturing a wiring board according to claim 4, wherein the component-accommodating substrate is formed such that the first surface of the component-accommodating substrate forms an IC mounting side and the second surface of the component-accommodating substrate forms a second wiring board connection side.

13. A method for manufacturing a wiring board according to claim 5, wherein the component-accommodating substrate is formed such that the first surface of the component-accommodating substrate forms an IC mounting side and the second surface of the component-accommodating substrate forms a second wiring board connection side.

14. A method for manufacturing a wiring board according to claim 6, wherein the component-accommodating substrate is formed such that the first surface of the component-accommodating substrate forms an IC mounting side and the second surface of the component-accommodating substrate forms a second wiring board connection side.

15. A method for manufacturing a wiring board according to claim 7, wherein the component-accommodating substrate is formed such that the first surface of the component-accommodating substrate forms an IC mounting side and the second surface of the component-accommodating substrate forms a second wiring board connection side.

16. A method for manufacturing a wiring board according to claim 8, wherein the component-accommodating substrate is formed such that the first surface of the component-accommodating substrate forms an IC mounting side and the second surface of the component-accommodating substrate forms a second wiring board connection side.

17. A method for manufacturing a wiring board according to claim 1, further comprising:
attaching a first surface of a second component-accommodating substrate to the support sheet on an opposite side with respect to the component-accommodating substrate.

18. A method for manufacturing a wiring board according to claim 1, further comprising:
attaching a first surface of a second component-accommodating substrate to the support sheet on an opposite side with respect to the component-accommodating substrate;
forming a connection layer comprising a plurality of insulation layers and a plurality of wiring-pattern layers on a second surface of the second component-accommodating substrate on an opposite side with respect to the first surface of the second component-accommodating substrate; and
removing the component-accommodating substrate and the second component-accommodating substrate from the support sheet such that the intermediate laminate structure and a second intermediate structure comprising the connection layer laminated on the second surface of the second component-accommodating substrate are formed.

19. A method for manufacturing a wiring board according to claim 1, wherein each of the upper-layer structures is formed such that each of the upper-layer structures includes a plurality of insulation layers.

20. A method for manufacturing a wiring board according to claim 1, wherein the electronic component is a multi-layer ceramic capacitor, the forming of the intermediate structures includes forming a via conductor through the intermediate insulation layer on one of the upper and lower surfaces of the substrate such that the via conductor connects an electrode of the multi-layer ceramic capacitor and the intermediate wiring-pattern layer on the one of the upper and lower surfaces of the substrate, and the forming of the connection layer includes forming a plurality of filled via conductors through the insulation layers in the connection layers such that the plurality of via conductors is stacked on the via conductor in the intermediate insulation layer on the one of the upper and lower surfaces of the substrate and is stacked one another to form a stacked via structure.
